(19) United States
(12) Patent Application Publication
(10) Pub. No.: US 2013/0161613 A1
(43) Pub. Date: Jun. 27, 2013

(54) Ultraviolet Sensor and Method for Manufacturing the Same

(71) Applicant: MURATA MANUFACTURING CO., LTD., Nagaokakyo-Shi (JP)

(72) Inventor: Kazutaka Nakamura, Nagaokakyo-shi (JP)

(73) Assignee: MURATA MANUFACTURING CO., LTD., Nagaokakyo-Shi (JP)

(21) Appl. No.: 13/771,195

(22) Filed: Feb. 20, 2013

Related U.S. Application Data
(63) Continuation of application No. PCT/JP2011/067959, filed on Aug. 5, 2011.

(30) Foreign Application Priority Data
Aug. 20, 2010 (JP) 2010-184671

(51) Int. Cl. H01L 31/0256; H01L 31/18

(52) U.S. Cl. CPC H01L 31/0256; H01L 31/18
USPC 257/43; 438/85

(57) ABSTRACT

An ultraviolet sensor that includes a p-type semiconductor layer principally composed of (Ni, Zn)O, an n-type semiconductor layer composed of ZnO which is joined to the p-type semiconductor layer, an internal electrode embedded in the p-type semiconductor layer, and first and second terminal electrodes formed at both ends of the p-type semiconductor layer. The surface roughness of the p-type semiconductor layer is 1.5 μm or less, and preferably 0.3 μm or more and 1.0 μm or less. In a manufacturing process, the formed product prior to firing and/or the p-type semiconductor layer after firing is polished by barrel polishing so that the surface roughness Ra thereof is 1.0 μm or less. Thereby, light absorption efficiency can be improved to directly detect a desired large photocurrent and secure high reliability, and a spectral property can be controlled to strongly respond to various wavelength bands of ultraviolet light.

### CROSS REFERENCE TO RELATED APPLICATIONS

The present application is a continuation of International application No. PCT/JP2011/067959, filed Aug. 5, 2011, which claims priority to Japanese Patent Application No. 2010-184671, filed Aug. 20, 2010, the entire contents of each of which are incorporated herein by reference.

### FIELD OF THE INVENTION

The present invention relates to an ultraviolet sensor, and a method for manufacturing an ultraviolet sensor, and more particularly relates to a photodiode type ultraviolet sensor having a laminate structure in which a p-type semiconductor layer is joined to an n-type semiconductor layer in the form of a hetero junction by using an oxide compound semiconductor, and a method for manufacturing the same.

### BACKGROUND OF THE INVENTION

An ultraviolet sensor has been widely used as an ultraviolet detection device of a germicidal lamp for sterilizing bacteria floating in air or water, an ultraviolet irradiation apparatus or the like, and in recent years, the ultraviolet sensor has also been expected to be applied to an optical communication device.

As this type of ultraviolet sensor, hitherto, a sensor using a diamond semiconductor or a SiC semiconductor as a sensing material has been known. However, these diamond semiconductors and SiC semiconductors have defects that the ability of materials to be processed is inferior and the materials are expensive.

Hence, in recent years, the oxide semiconductor which is easy in material processing and relatively inexpensive has received attention, and research on and development of an ultraviolet sensor formed by joining a p-type semiconductor layer to an n-type semiconductor layer in the form of a hetero junction by using these oxide semiconductors are actively pursued.

For example, in Patent Document 1, there is proposed an ultraviolet sensor which includes a (Ni, Zn)O layer composed of an oxide compound semiconductor formed by dissolving ZnO in NiO, a thin film material layer formed so as to cover a part of one main surface of the (Ni, Zn)O layer by a sputtering method, and a first and a second terminal electrodes formed at both ends of the (Ni, Zn)O layer, and in which an internal electrode is formed in the (Ni, Zn)O layer, the first terminal electrode is electrically connected to the internal electrode and the second terminal electrode is electrically connected to the thin film material layer.

In Patent Document 1, ultraviolet light to be detected does not have to transmit the thin film material layer and reach an upper junction part, and the junction part is directly irradiated with ultraviolet light. Therefore, it is possible to avoid the sensitivity of an ultraviolet sensor from deteriorating by decay of ultraviolet light in transmitting the thin film material layer. Particularly, when the thin film material layer is made of ZnO, it is possible to obtain an ultraviolet sensor having relatively high wavelength selectivity.
Patent Document 1: JP 2010-87482 A (claim 1)

### SUMMARY OF THE INVENTION

However, in Patent Document 1, since a sintered surface of the (Ni, Zn)O layer has projections and depressions, there is a problem that when a thin film material layer such as ZnO is formed on the (Ni, Zn)O layer and the layer is irradiated with ultraviolet light, diffuse reflection occurs at the surface of the thin film material layer or at a junction interface between the (Ni, Zn)O layer and the thin film material layer, and light transmittance is decreased, and therefore light absorption efficiency is low.

That is, in Patent Document 1, since the carrier concentration of the (Ni, Zn)O layer is extremely lower than the carrier concentration of the thin film material layer such as a ZnO layer and further light absorption efficiency is low as described above, a sufficient photocurrent cannot be attained. Therefore, ultraviolet light had to be detected by changes in a resistance by externally disposing a power source circuit.

As described above, in Patent Document 1, since the intensity of ultraviolet light has to be detected as changes in a resistance value by externally disposing a power source circuit, there were problems that a mounting space for the power source circuit had to be secured, resulting in upsizing of a device.

Furthermore, as described above, since the surface of the (Ni, Zn)O layer after firing has projections and depressions, there is a probability that a junction defect occurs between the internal electrode and the terminal electrode, or defects such as pinhole remain at the surface and therefore an open defect or a short circuit defect occurs to impair reliability.

On the other hand, in the case of the ultraviolet sensor, it needs to detect ultraviolet light at various wavelength bands according to uses. For example, when the ultraviolet sensor is used for a germicidal lamp or the like, the sensor needs to respond at a wavelength band of about 230 to 330 nm (including UV-B and UV-C), and when the ultraviolet sensor is used for an industrial ultraviolet irradiation apparatus, the sensor needs to respond at a wavelength band of about 350 to 370 nm (UV-A). Accordingly, it is favorable if an ultraviolet sensor, which strongly responds at various wavelength bands in the case of the same material system, can be realized.

However, in a conventional ultraviolet sensor described in Patent Document 1, since a wavelength responsive property is controlled by absorption characteristics of a material, it is difficult to control the wavelength responsive property by only the species of a material, and therefore, it is difficult to attain an ultraviolet sensor which responds at various wavelength bands in the case of the same material system.

The present invention was made in view of such a situation, and it is an object of the present invention to provide an ultraviolet sensor which can directly detect a desired large photocurrent by improving light absorption efficiency and secure high reliability, and can strongly respond to various wavelength bands of ultraviolet light by controlling a wavelength responsive property, and a method for manufacturing the ultraviolet sensor.

The present inventor made earnest investigations concerning an ultraviolet sensor which uses an oxide compound semiconductor principally composed of (Ni, Zn)O as a p-type semiconductor layer and uses an oxide semiconductor principally composed of ZnO as an n-type semiconductor layer, and in which an internal electrode is embedded in the p-type semiconductor layer, and consequently the present inventor obtained findings that by adjusting the surface roughness Ra of the p-type semiconductor layer to 1.5 μm or less, preferably 0.3 μm or more and 1.0 μm or less, projections and depressions of the surface of the p-type semiconductor layer are reduced to improve a joining property between the internal electrode and the terminal electrode, and light absorption efficiency can be outstandingly improved.

The present invention was made based on such findings, and an ultraviolet sensor of the present invention is an ultraviolet sensor including a p-type semiconductor layer principally composed of a solid solution of NiO and ZnO, an n-type semiconductor layer principally composed of ZnO and joined to the p-type semiconductor layer in the form in which a part of a surface of the p-type semiconductor layer is exposed, an internal electrode embedded in the p-type semiconductor layer, and terminal electrodes formed at both ends of the p-type semiconductor layer, wherein the p-type semiconductor layer has a surface roughness Ra of 1.5 μm or less.

In addition, in the present invention, the surface roughness refers to arithmetic average roughness (hereinafter, referred to as a “surface roughness Ra”).

Further, in the ultraviolet sensor of the present invention, the p-type semiconductor layer preferably has a surface roughness Ra of 1.0 μm or less.

Further, in the ultraviolet sensor of the present invention, the p-type semiconductor layer preferably has a surface roughness Ra of 0.3 μm or more.

Further, as a result of further earnest investigation of the present inventor, the inventor obtained a finding that in the above material system, when the surface roughness Ra of the formed product prior to firing or the fired p-type semiconductor layer is adjusted, a wavelength responsive property can be controlled, and thereby an ultraviolet sensor capable of strongly responding to various wavelength bands of ultraviolet light can be obtained.

Specifically, by surface polishing the formed product prior to firing so that the surface roughness Ra of the formed product is 1.0 μm or less, an ultraviolet sensor selectively responding to ultraviolet light at a wavelength band of 230 to 330 nm can be obtained, and by surface polishing the p-type semiconductor layer after firing so that the surface roughness Ra of the p-type semiconductor layer is 1.0 μm or less, an ultraviolet sensor, which can strongly respond to ultraviolet light having a wavelength band of 350 to 370 nm and can also respond to ultraviolet light having a wavelength band of 230 to 330 nm, can be obtained. Moreover, when both surface polishing procedures are combined, an ultraviolet sensor, which more sharply responds to ultraviolet light having a wide wavelength band of 230 to 370 nm, can be obtained.

That is, a method for manufacturing an ultraviolet sensor of the present invention is a method for manufacturing an ultraviolet sensor including a green sheet preparation step of preparing a plurality of green sheets principally composed of a solid solution of NiO and ZnO; a conductive film formation step of applying a conductive paste onto the surface of a green sheet of the plurality of green sheets to form a conductive film having a predetermined pattern; a formed product preparation step of laminating the plurality of the green sheets in the form in which the green sheet having the conductive film formed thereon is supported by being sandwiched to form a formed product; and a firing step of firing the formed product to prepare a p-type semiconductor layer, wherein the method for manufacturing an ultraviolet sensor includes a first polishing step of surface-polishing the formed product as a substance to be polished before performing the firing step, and in the first polishing step, the formed product is surface polished so that its surface roughness Ra is 1.0 μm or less.

Further, a method for manufacturing an ultraviolet sensor of the present invention is a method for manufacturing an ultraviolet sensor including a green sheet preparation step of preparing a plurality of green sheets principally composed of a solid solution of NiO and ZnO; a conductive film formation step of applying a conductive paste onto the surface of a green sheet of the plurality of green sheets to form a conductive film having a predetermined pattern; a formed product preparation step of laminating the plurality of the green sheets in the form in which the green sheet having the conductive film formed thereon is supported by being sandwiched to form a formed product; and a firing step of firing the formed product to prepare a p-type semiconductor layer, wherein the method for manufacturing an ultraviolet sensor includes a second polishing step of surface-polishing the p-type semiconductor layer as a substance to be polished, and in the second polishing step, the p-type semiconductor layer is surface polished so that its surface roughness is 1.0 μm or less.

Moreover, a method for manufacturing an ultraviolet sensor of the present invention is a method for manufacturing an ultraviolet sensor including a green sheet preparation step of preparing a plurality of green sheets principally composed of a solid solution of NiO and ZnO; a conductive film formation step of applying a conductive paste onto the surface of a green sheet of the plurality of green sheets to form a conductive film having a predetermined pattern; a formed product preparation step of laminating the plurality of the green sheets in the form in which the green sheet having the conductive film formed thereon is supported by being sandwiched to form a formed product; and a firing step of firing the formed product to prepare a p-type semiconductor layer, wherein the method for manufacturing an ultraviolet sensor includes a first polishing step of surface-polishing the formed product as a substance to be polished before performing the firing step and a second polishing step of surface-polishing the p-type semiconductor layer as a substance to be polished, and in the first polishing step, the formed product is surface polished so that its surface roughness is 1.0 μm or less, and in the second polishing step, the p-type semiconductor layer is surface polished so that its surface roughness is 1.0 μm or less.

The above-mentioned surface polishing can be performed efficiently and in high volume by barrel polishing.

That is, in the method for manufacturing an ultraviolet sensor of the present invention, as the surface polishing, barrel polishing is preferably performed by charging the substance to be polished into a container together with media, and rotating, vibrating, inclining or swinging the container.

Further, the method for manufacturing an ultraviolet sensor of the present invention includes an n-type semiconductor layer formation step of forming an n-type semiconductor layer principally composed of ZnO on the surface of the p-type semiconductor layer in the form in which a part of the surface of the p-type semiconductor layer is exposed, wherein the n-type semiconductor layer formation step preferably includes a ZnO sintered body preparation step of preparing a ZnO sintered body principally composed of ZnO, and a sputtering step of sputtering by using the ZnO sintered body as a target to form the n-type semiconductor layer.

The method for manufacturing an ultraviolet sensor of the present invention preferably includes a terminal electrode formation step of forming terminal electrodes at both ends of the p-type semiconductor layer.

### EFFECT OF THE INVENTION

In accordance with the ultraviolet sensor of the present invention, since the p-type semiconductor layer has a surface roughness Ra of 1.5 μm or less (preferably 0.3 μm or more and 1.0 μm or less), projections and depressions of the surface of the p-type semiconductor layer are reduced to improve smoothness of the p-type semiconductor layer and enable an increase in an effective area, and diffuse reflection at the surface of the n-type semiconductor layer and at a junction interface between the p-type semiconductor layer and the n-type semiconductor layer is suppressed, and ultraviolet light can be transmitted efficiently. Further, since projections and depressions of the surface of the p-type semiconductor layer are reduced, a joining property between the internal electrode and the terminal electrode is improved, unnecessary contact resistance is decreased, and a junction defect can be inhibited. Thereby, light absorption efficiency can be outstandingly improved, and it is unnecessary to detect the intensity of ultraviolet light as changes in a resistance value by externally disposing a power source circuit like a conventional ultraviolet sensor, and it becomes possible to directly detect a desired large photocurrent. Further, since a contact defect or a junction defect is suppressed, a short circuit defect or an open defect can be reduced, and a highly reliable ultraviolet sensor can be attained.

Further, in accordance with the method for manufacturing an ultraviolet sensor of the present invention, since the method for manufacturing an ultraviolet sensor includes the first polishing step of surface-polishing the formed product as a substance to be polished before performing the firing step, and in the first polishing step, the formed product is surface polished so that its surface roughness is 1.0 μm or less, and then the firing step is performed, the vicinity of the surface becomes small in the amount of carrier by volatilization of Zn during firing. Then, since the carrier moves from the n-type semiconductor layer having a high carrier concentration to the p-type semiconductor layer having a low carrier concentration, the depletion layer is substantially formed only in the vicinity of a surface layer on a p-type semiconductor layer side, and thereby an ultraviolet sensor effectively responding to only a wavelength band of 230 to 330 nm originated from (Ni, Zn)O can be obtained.

Further, in accordance with the method for manufacturing an ultraviolet sensor of the present invention, since the method includes the second polishing step of surface polishing the p-type semiconductor layer as a substance to be polished, and in the second polishing step, the p-type semiconductor layer is surface polished so that its surface roughness is 1.0 μm or less, the surface of the p-type semiconductor layer, in which the amount of carrier is small, is scraped off in the second polishing step, and therefore the p-type semiconductor layer is joined to the n-type semiconductor layer in a state in which a carrier concentration is moderately stable. Thereby, the depletion layer is formed in both of the vicinity of an interface on an n-type semiconductor layer side and the vicinity of an interface on a p-type semiconductor layer side, and an ultraviolet sensor sharply responding to a wavelength band of 350 to 370 nm and also effectively responding to a wavelength band of 230 to 330 nm can be obtained. Further, since the p-type semiconductor layer is surface polished, a probability of a junction region of the n-type semiconductor layer and the p-type semiconductor layer is increased, and an effective area is increased and reflected light can be used, and therefore absorption efficiency is increased and the sensor more sharply responds.

Further, since the method for manufacturing an ultraviolet sensor of the present invention includes a first polishing step of surface-polishing the formed product as a substance to be polished before performing the firing step and a second polishing step of surface-polishing the p-type semiconductor layer as a substance to be polished, and in the first polishing step, the formed product is surface polished so that its surface roughness is 1.0 μm or less, and in the second polishing step, the p-type semiconductor layer is surface polished so that its surface roughness is 1.0 μm or less, there is synergy between the effect of surface polishing before firing and the effect of surface polishing after firing, and a highly reliable ultraviolet sensor which more sharply responds and has a larger photocurrent at a wide wavelength band of 230 to 370 nm can be obtained.

Further, in the surface polishing, a polished substance having a desired surface roughness Ra can be obtained with a high degree of efficiency by charging the substance to be polished into a container together with media, and rotating, vibrating, inclining or swinging the container to perform barrel polishing.

As described above, in accordance with the manufacturing method of the present invention, by surface polishing the formed product and/or the p-type semiconductor layer to adjust the surface roughness Ra to 1.0 μm or less, an ultraviolet sensor, which can directly detect a large photocurrent responding to various wavelength bands even in the case of the same material system and has high sensitivity of light-receiving, can be realized.

### BRIEF EXPLANATION OF THE DRAWINGS

FIG. 1 is a sectional view schematically showing an embodiment of an ultraviolet sensor of the present invention.

FIG. 2 is an exploded perspective view of a formed product prior to firing.

FIG. 3 is a view showing a measurement method of an output current of an example.

FIG. 4 is a view showing a wavelength responsive property of a sample No. 3 together with a wavelength responsive property of a sample No. 1.

FIG. 5 is a view showing a wavelength responsive property of a sample No. 8 together with a wavelength responsive property of a sample No. 1.

### DESCRIPTION OF THE PREFERRED EMBODIMENTS OF THE INVENTION

Next, with reference to accompanying drawings, embodiments of the present invention will be described in detail.

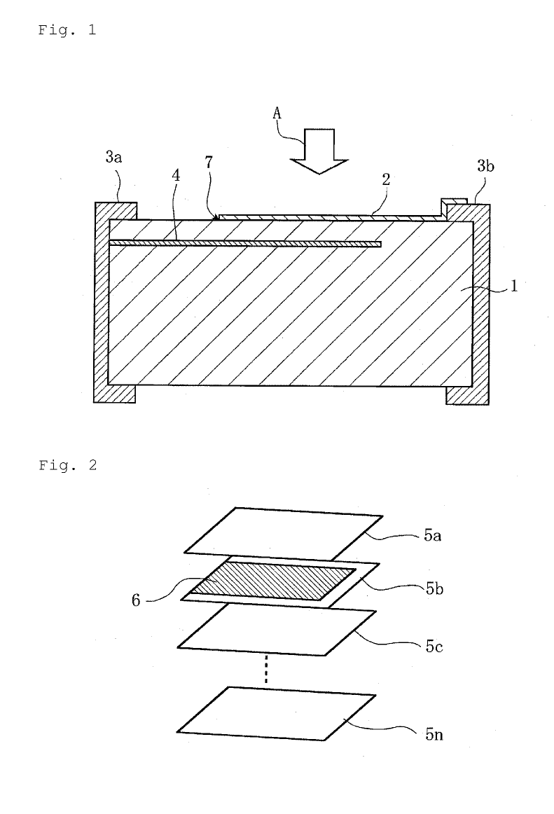

FIG. 1 is a sectional view schematically showing an embodiment of an ultraviolet sensor of the present invention.

That is, this ultraviolet sensor has a p-type semiconductor layer 1 principally composed of a solid solution of NiO and ZnO, and an n-type semiconductor layer 2 principally composed of ZnO, and the n-type semiconductor layer 2 is joined to the p-type semiconductor layer 1 in the form in which a part of the surface of the p-type semiconductor layer 1 is exposed.

The p-type semiconductor layer 1 can be represented by a general formula (Ni₁₋ₓZnₓ)O (hereinafter, denoted by (Ni, Zn)O), and the compounding molar ratio x of Zn preferably satisfies a relationship of 0.2≦x≦0.4 from the viewpoint of stably obtaining good sensitivity. The reason for this is that when x is less than 0.2, the content of Ni is excessive, and therefore there is a possibility of an increase in a resistance. On the other hand, when x is more than 0.4, the content of Zn is excessive, and therefore there is a possibility that ZnO grains are precipitated at a crystal grain boundary and (Ni, Zn)O is converted to an n-type semiconductor.

Further, the n-type semiconductor layer 2 is principally composed of the ZnO and contains a trace amount of Al, Co, In, Ga or the like as a dopant. By containing such a dopant, this layer is provided with a conductive property and converted to an n-type semiconductor. In addition, the n-type semiconductor layer 2 may contain trace amounts of other additives, and may contain, for example, Fe, Ni or Mn as a diffusing agent. Also, it may include a trace amount of Zr, Si or the like as an impurity, which does not affect semiconductor properties.

Further, a first terminal electrode 3a and a second terminal electrode 3b are formed at both ends of the p-type semiconductor layer 1. An internal electrode 4 is embedded in the upper portion of the p-type semiconductor layer 1 with an end of the internal electrode exposed to a surface, and the first terminal electrode 3a is formed at one end of the p-type semiconductor layer 1 so as to be electrically connected to the internal electrode 4. The second terminal electrode 3b is formed at the other end of the p-type semiconductor layer 1 so as to be electrically connected to the n-type semiconductor layer 2.

In addition, in the first and second terminal electrodes 3a and 3b, a first plating film made of Ni or the like and a second plating film made of Sn or the like are formed in succession on the surface of an external electrode made of Ag or the like.

Further, the internal electrode 4 is made of a composite oxide with a low resistance containing an oxide having a perovskite structure represented by a general formula RNiO₃ or an oxide represented by a general formula R₂NiO₄, which is principally composed of a rare earth element R and Ni.

That is, the composite oxide principally composed of a rare earth element R and Ni is an Ni-base oxide as with (Ni, Zn)O, and since both of the composite oxide and (Ni, Zn)O are close in energy level to each other, they can prevent an unnecessary Schottky barrier from being formed between the composite oxide and (Ni, Zn)O and are close to ohmic contact with each other. Further, since the rare earth element is hardly diffused to a (Ni, Zn)O side compared with Ni, and does not have the oxygen release action contrasted with Pd, the composite oxide enables to reduce the specific resistance of (Ni, Zn)O. Furthermore, since the composite oxide principally composed of a rare earth element R and Ni is an Ni-base oxide as with (Ni, Zn)O, as described above, it is close to (Ni, Zn)O in shrinkage behavior at elevated temperatures, and therefore it hardly causes delamination between the p-type semiconductor layer 2 and the internal electrode 4 and does not cause a phenomenon in which an electrode is drawn into the inside of a sintered body. Further, since an expensive noble metal material such as Pt or Pd does not have to be used, an increase in price of the ultraviolet sensor can be suppressed.

For the above reason, in the present embodiment, the internal electrode 4 is made of a composite oxide with a low resistance containing an oxide having a perovskite structure represented by a general formula RNiO₃ or an oxide represented by a general formula R₂NiO₄, which is principally composed of a rare earth element R and Ni.

Then, such a rare earth element is not particularly limited as long as it has a low resistance when it forms a composite oxide with Ni, and for example, at least one selected from among La, Pr, Nd, Sm, Gd, Dy, Ho, Er and Yb may be used. In addition, among these elements, inexpensive La is preferably used from the viewpoint of economics.

In the ultraviolet sensor thus formed, when the sensor is irradiated with ultraviolet light as shown by an arrow A, and a depletion layer formed at a joint interface 7 between the n-type semiconductor layer 2 and the p-type semiconductor layer 1 is irradiated with ultraviolet light, carriers are excited, and thereby a photocurrent is generated; hence, by detecting this photocurrent, the intensity of ultraviolet light can be detected.

In the present embodiment, the surface roughness Ra of the p-type semiconductor layer 1 is controlled to be 1.5 μm or less, and projections and depressions of the surface of the p-type semiconductor layer 1 are reduced. Thereby, light absorption efficiency can be outstandingly improved, a short circuit defect or an open defect can be reduced, and reliability can be improved.

That is, in the p-type semiconductor layer 1, the surface has projections and depressions in a state of being fired. Accordingly, when the n-type semiconductor layer 2 is formed on the surface of the p-type semiconductor layer 1, an interface between the n-type semiconductor layer 2 and the p-type semiconductor layer 1 is joined in a concave-convex form, and the surface of the n-type semiconductor layer 2 also has projections and depressions. Therefore, when ultraviolet light is irradiated from an arrow A direction, the ultraviolet light causes diffuse reflection at a junction interface 7 and at the surface of the n-type semiconductor layer 2 and transmittance is decreased, resulting in a reduction of light absorption efficiency.

Further, the internal electrode 4 is embedded in the p-type semiconductor layer 1, and if the surface of a side of the p-type semiconductor layer 1 is formed in concave-convex form, when a first and a second terminal electrodes 3a, 3b are formed thereafter, unnecessary contact resistance or a junction defect may occur between the internal electrode 4 and the first terminal electrode 3a. Moreover, there is a probability that defects such as pinholes, formed during manufacturing, remain at the surface of the p-type semiconductor layer 1. This unnecessary contact resistance or a junction defect and defects such as a pinholes may cause an open defect or a short circuit defect, resulting in a reduction of reliability.

Then, in the present embodiment, surface roughness Ra of the p-type semiconductor layer 1 is suppressed to 1.5 μm or less, preferably 1.0 μm or less, and thereby, projections and depressions of the surface of the p-type semiconductor layer 1 are reduced. By reducing projections and depressions of the surface of the p-type semiconductor layer 1 like this, diffuse reflection of incident ultraviolet light at a junction interface 7 and at the surface of the n-type semiconductor layer 2 is suppressed, and transmittance of ultraviolet light is improved, and an effective area involved in the ultraviolet light detection can be increased. Further, since a joining property between the internal electrode 4 and the first terminal electrode 3a is improved and unnecessary contact resistance can be reduced, light-absorption can be performed with high efficiency.

As described above, in the present invention, light absorption efficiency can be outstandingly improved, and a large photocurrent can be obtained for ultraviolet light that enters. Accordingly, since it becomes unnecessary to detect the intensity of ultraviolet light as changes in a resistance value, the need for externally disposing a power source circuit is eliminated, and therefore downsizing/cost reduction of a device can be realized.

Furthermore, as described above, since a joining property between the internal electrode 4 and the first and second terminal electrodes 3a, 3b is improved, and it becomes possible to remove the defects such as a pinhole formed at the formed product by surface polishing, the occurrences of an open defect or a short circuit defect can be suppressed, and the reliability can be improved.

In addition, when the surface roughness Ra is more than 1.5 μm, projections and depressions of the surface cannot be adequately reduced, and therefore it is difficult to exert the effect of improving light absorption efficiency. Further, there is a possibility that a short circuit defect or an open defect is produced, and it is difficult to secure adequate reliability. Accordingly, the surface roughness Ra has to be suppressed at least to 1.5 μm or less.

A lower limit of the surface roughness Ra of the p-type semiconductor layer is not particularly limited, but the lower limit is preferably equal to or longer than an absorption wavelength inherent in the material composing the p-type semiconductor layer 1. That is, since an absorption wavelength of (Ni, Zn)O composing the p-type semiconductor layer 1 is 230 to 330 nm, the lower limit of the surface roughness Ra is preferably, for example, 0.3 μm (300 nm) or more.

A polishing technique of surface polishing is not particularly limited, but a barrel polishing method, in which surface polishing can be performed in large amounts and with efficiency and a manufacturing process is not complicated, is preferably used.

That is, the surface polishing can be performed by charging many substances to be polished, media such as alumina beads, and pure water to be added as required into a barrel container, and rotating, vibrating, inclining or swinging the barrel container for such a predetermined time that the surface roughness Ra is 1.5 μm or less, and preferably 0.3 μm or more and 1.0 μm or less. Thereby, a large amount of a substance to be polished can be polished to a desired surface roughness Ra with efficiency.

In addition, when the surface roughness Ra of the p-type semiconductor layer 1 can be controlled to be 1.5 μm or less, the formed product prior to firing may be surface polished as a substance to be polished, or the p-type semiconductor layer 1 after firing may be surface polished as a substance to be polished, or both of the formed product prior to firing and the p-type semiconductor layer 1 after firing may be surface polished as substances to be polished.

As described above, in the present embodiment, the surface roughness Ra is 1.5 μm or less (preferably 0.3 μm or more and 1.0 μm or less), and therefore, projections and depressions of the surface of the p-type semiconductor layer 1 are reduced to improve smoothness of the p-type semiconductor layer 1 and enable an increase in an effective area, and diffuse reflection at the surface of the n-type semiconductor layer 2 and at a junction interface 7 between the p-type semiconductor layer 1 and the n-type semiconductor layer 2 is suppressed, and ultraviolet light can be transmitted efficiently.

Further, since projections and depressions of the surface of the p-type semiconductor layer 1 are reduced, a joining property between the internal electrode 4 and the first and second terminal electrodes 3a, 3b is improved, unnecessary contact resistance is decreased, and a junction defect can be inhibited.

Thereby, light absorption efficiency can be outstandingly improved, and it is unnecessary to detect the intensity of ultraviolet light as changes in a resistance value by externally disposing a power source circuit like a conventional ultraviolet sensor, and it becomes possible to directly detect a desired large photocurrent. Further, since a contact defect or a junction defect is suppressed, a short circuit defect or an open defect can be reduced, and a highly reliable ultraviolet sensor can be attained.

Further, in the present invention, it becomes possible to control a wavelength responsive property even in the same material system by surface polishing one of or both of the formed body and the p-type semiconductor layer 1.

For example, when surface polishing is performed so that the surface roughness Ra of the formed product prior to firing is 1.0 μm or less, it becomes possible to realize an ultraviolet sensor which can attain good sensitivity of light-receiving only at a wavelength band of 230 to 330 nm (including UV-B and UV-C) like that of a germicidal lamp.

That is, in a photodiode type ultraviolet sensor, as described above, the depletion layer is irradiated with ultraviolet light, and thereby carriers are excited to produce a photocurrent. In addition, in general, when an electron of the n-type semiconductor layer 2 moves to the p-type semiconductor layer 1 side, and the hole of the p-type semiconductor layer 1 moves to the n-type semiconductor layer 2 side, both of the hole and the electron are coupled with each other and disappear in the vicinity of the junction interface, and thereby, a depletion layer is formed.

However, when the formed product to become a p-type semiconductor layer 1 is surface polished to adjust its surface roughness Ra to 1.0 μm or less and then fired, Zn is volatilized in a firing process since it is easy to volatilize, and thereby the vicinity of the surface of the p-type semiconductor layer 1 becomes small in the amount of carrier.

Then, when the n-type semiconductor layer 2 is formed on the p-type semiconductor layer 1 using a ZnO base material, a carrier concentration of (Ni, Zn)O is extremely lower than a carrier concentration of ZnO, and a carrier moves from a region having a high concentration to a region having a low concentration. Therefore, while a hole of the p-type semiconductor layer 1 having a low carrier concentration remains in the p-type semiconductor layer 1, an electron of the n-type semiconductor layer 2 having a high carrier concentration moves to a direction of the p-type semiconductor layer 1. Consequently, the hole is coupled with the electron and disappears in the vicinity of a surface layer of the p-type semiconductor layer 1, and a depletion layer in which a carrier does not exist is formed on the p-type semiconductor layer 1 side.

That is, in this case, the depletion layer is substantially formed only in the vicinity of a surface layer on a p-type semiconductor layer 1 side. Accordingly, when the depletion layer is irradiated with ultraviolet light, the intensity of ultraviolet light strongly responding to a wavelength band of 230 to 330 nm originated from the p-type semiconductor layer 1, or (Ni, Zn)O can be detected as a photocurrent.

Further, when surface polishing is performed so that the surface roughness Ra of the p-type semiconductor layer 1 after firing is 1.0 μm or less, it becomes possible to realize an ultraviolet sensor which sharply responds to 350 to 370 nm (UV-A) which is a wavelength band of an industrial ultraviolet irradiation apparatus and also has good sensitivity of light-receiving at a wavelength band of 230 to 330 nm (including UV-B and UV-C).

That is, when the fired p-type semiconductor layer 1 is scraped off by a predetermined thickness (for example, 100 nm or more) in a depth direction from the surface to suppress the surface roughness Ra to 1.0 μm or less, the surface of the p-type semiconductor layer 1, in which the amount of carrier is small, is scraped off, and an interface between the p-type semiconductor layer 1 and the n-type semiconductor layer 2 has a moderate carrier concentration, and the p-type semiconductor layer 1 is appropriately joined to the n-type semiconductor layer 2. Consequently, a carrier (hole) of the p-type semiconductor layer 1 moves to a direction of the n-type semiconductor layer 2, and a carrier (electron) of the n-type semiconductor layer 2 moves to a direction of the p-type semiconductor layer 1, and both of the hole and the electron are coupled with each other in the vicinity of the interface and disappear, and a depletion layer is formed on both of a p-type semiconductor layer 1 side and a n-type semiconductor layer 2 side of the junction interface 7.

Accordingly, when the depletion layer is irradiated with ultraviolet light, it is possible to detect a large photocurrent extremely sharply responding to 350 to 370 nm originated from ZnO and also effectively responding to 230 to 330 nm originated from (Ni, Zn)O.

Further, when surface polishing is performed so that the surface roughness Ra is 1.0 μm or less for both of the formed product prior to firing and the p-type semiconductor layer 1 after firing, there is synergy between the effect of surface polishing before firing and the effect of surface polishing after firing, it becomes possible to obtain a highly reliable ultraviolet sensor which more sharply responds and has a larger photocurrent at a wide wavelength band of 230 to 370 nm.

As described above, in accordance with the method for manufacturing an ultraviolet sensor of the present invention, it becomes possible to control a wavelength responsive property by surface polishing, as required, only a formed product, only a p-type semiconductor layer, or both of the formed product and the p-type semiconductor layer to adjust the surface roughness Ra to 1.0 μm or less, respectively.

Next, a method for manufacturing the above-mentioned ultraviolet sensor will be described in detail for the case where a formed product prior to firing is subjected to surface polish.

[Preparation of ZnO Sintered Body]

A ZnO powder, various doping agents, and an additive to be used as required such as a diffusing agent or the like are prepared and weighed in predetermined amounts. A solvent such as pure water is added to these weighed compounds, and the resulting mixture is adequately mixed and pulverized in a wet manner by using a ball mill employing balls such as PSZ (partially stabilized zirconia) beads or the like as a pulverizing medium to obtain a slurry-like mixture. Subsequently, after the slurry-like mixture is dehydrated and dried, the slurry is granulated to have a predetermined particle diameter, and then resulting grains are calcinated for about 2 hours at a predetermined temperature to obtain a calcined powder.

Next, after a solvent such as pure water is again added to the calcined powder thus obtained, the resulting mixture is adequately pulverized in a wet manner by using a ball mill employing balls as a pulverizing medium to obtain a slurry-like pulverized material. Next, the slurry-like pulverized material is dehydrated and dried, and then pure water, a dispersing agent, a binder, a plasticizer and the like are added to prepare a slurry for forming. Thereafter, the slurry for forming is subjected to forming by using a method of forming such as a doctor blade method to prepare a ZnO green sheet having a predetermined thickness. Subsequently, a predetermined number of the ZnO green sheets are laminated and then press-bonded to prepare a press-bonded product. Then, after the press-bonded product is degreased, it is fired to obtain a ZnO sintered body.

[Preparation of (Ni, Zn)O Green Sheet]

A NiO powder and a ZnO powder are weighed so that the compounding molar ratio x of Zn is 0.2 to 0.4, and a solvent such as pure water or the like is added to these weighed compounds, and the resulting mixture is adequately mixed and pulverized in a wet manner in a ball mill using balls as a pulverizing medium to obtain a slurry-like mixture. Subsequently, this mixture is dehydrated, dried, and granulated to have a predetermined particle diameter, and then calcinated for about 2 hours at a predetermined temperature to obtain a calcined powder. Next, after a solvent such as pure water is again added to the calcined powder thus obtained, the resulting mixture is adequately pulverized in a wet manner in a ball mill using balls as a pulverizing medium to obtain a slurry-like pulverized material. Next, the slurry-like pulverized material is dehydrated and dried, and then an organic solvent, a dispersing agent, a binder and a plasticizer are added to prepare a slurry for forming. Then, the slurry for forming is formed by using a method of forming such as a doctor blade method, and thereby, a (Ni, Zn)O green sheet having a predetermined thickness is obtained.

[Preparation of Paste for Forming Internal Electrode]

A NiO powder and a R₂O₃ powder (R: a rare earth element) are weighed so that the proportion of moles between these compounds is 2:1, and then a solvent such as pure water is added to these weighed compounds, and the resulting mixture is adequately mixed and pulverized in a wet manner in a ball mill using balls as a pulverizing medium to obtain a slurry-like mixture. Subsequently, after the slurry-like mixture is dehydrated and dried, the slurry is granulated to have a predetermined particle diameter, and then resulting grains are calcinated for about 2 hours at a predetermined temperature to obtain a calcined powder. Next, after a solvent such as pure water is again added to the calcined powder thus obtained, the resulting mixture is adequately pulverized in a wet manner in a ball mill using balls as a pulverizing medium to obtain a slurry-like pulverized material. Next, the slurry-like pulverized material is dehydrated and dried to obtain a composite oxide powder containing an oxide represented by a general formula RNiO₃ or an oxide represented by a general formula R₂NiO₄. Then, the obtained composite oxide powder is mixed with an organic vehicle and the resulting mixture is kneaded with a three roll mill to prepare a paste for forming an internal electrode.

In addition, the organic vehicle is formed by dissolving a binder resin in an organic solvent, and the proportion between the binder resin and the organic solvent is adjusted so as to be 1 to 3:7 to 9, for example, in terms of a volume ratio. The binder resin is not particularly limited, and for example, an ethyl cellulose resin, a nitrocellulose resin, an acrylic resin, an alkyd resin, or a combination of these resins can be used. Further, the organic solvent is not particularly limited, and α-terpineol, xylene, toluene, diethylene glycol monobutyl ether, diethylene glycol monobutyl ether acetate, diethylene glycol monoethyl ether, and diethylene glycol monoethyl ether acetate can be used singly, or can be used in combination thereof.

[Preparation of Formed Product]

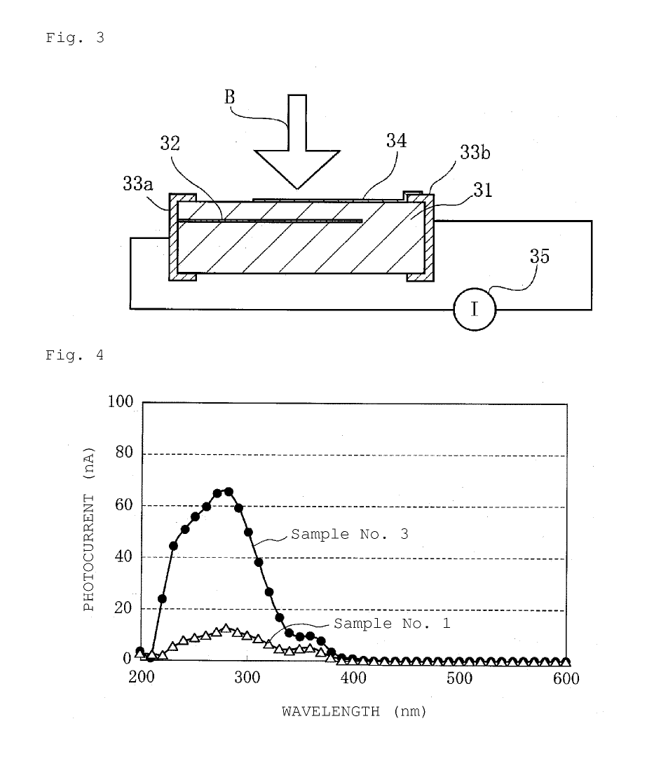

A method of preparing a formed product will be described with reference to FIG. 2.

First, the predetermined number of (Ni, Zn)O green sheets 5a, 5b, 5c, . . . , and 5n are prepared, and onto the surface of a (Ni, Zn)O green sheet 5b of these green sheets, the above-mentioned paste for forming an internal electrode is applied to form a conductive film 6.

Next, the predetermined number of (Ni, Zn)O green sheets 5c to 5n not provided with the conductive film are laminated, and the (Ni, Zn)O green sheet 5b provided with the conductive film 6 is laminated thereon, and further a (Ni, Zn)O green sheet 5a not provided with the conductive film is laminated thereon, and these sheets are press-bonded to prepare a formed product.

[Surface Polishing of Formed Product (First Polishing Step)]

Next, the surface of the formed product as a substance to be polished is surface polished, for example, by rotating-barrel polishing or the like so that its surface roughness Ra is 1.0 μm or less.

That is, a formed product as a substances to be polished and media such as alumina beads were charged in large amounts into a barrel container with a predetermined volume, and the barrel container is driven for a predetermined time so that the surface roughness Ra of the formed product is 1.0 μm or less to surface polish the substance to be polished. The predetermined time during which the barrel container is driven varies depending on a volume of the barrel container and charged amounts of the substance to be polished and the medium, and it is, for example, about 60 to 960 minutes.

[Preparation of P-Type Semiconductor Layer 1]

The formed product surface polished is adequately degreased, and then fired at a temperature around 1200° C. for about 5 hours to simultaneously fire the conductive film 6 and the (Ni, Zn)O green sheets 5a to 5n, and thereby, a p-type semiconductor layer 1 in which an internal electrode 4 is embedded is obtained.

[Preparation of Terminal Electrode 3a, 3b]

A paste for forming an external electrode is applied to both ends of the p-type semiconductor layer 1 and fired to form an external electrode. Herein, a conductive material of the paste for forming an external electrode is not particularly limited as long as it has a good electric conductivity, and Ag, Ag—Pd and the like can be used as the conductive material.

Thereafter, electroplating is performed to form a plating film having a two-layer structure composed of a first plating film and a second plating film, and thereby, a first terminal electrode 3a and a second terminal electrode 3b are formed.

[Formation of N-Type Semiconductor Layer 2]

Sputtering is performed through a metal mask having a predetermined opening using a ZnO sintered body as a target to form an n-type semiconductor layer 2 composed of a ZnO-base thin film on the surface of a p-type semiconductor layer 1 so that a part of the surface of the p-type semiconductor layer 1 is exposed and the n-type semiconductor layer 2 is electrically connected to a second terminal electrode 3b, and thereby, an ultraviolet sensor is obtained.

By employing the method including a first polishing step of surface-polishing the formed product as a substance to be polished before performing the firing step, as described above, wherein in the first polishing step, the layered product is surface polished so that its surface roughness is 1.0 μm or less, the depletion layer is substantially formed in the vicinity of a surface layer on a p-type semiconductor layer 1 side, and therefore an ultraviolet sensor responding to a wavelength band of 230 to 330 nm originated from (Ni, Zn)O efficiently can be obtained.

In addition, when only the p-type semiconductor layer 1 is surface polished, the p-type semiconductor layer 1 may be polished as a substance to be polished by rotating-barrel polishing as the second polishing step in place of the above first polishing step so that its surface roughness Ra is 1.0 μm or less.

That is, a p-type semiconductor layer 1 as a substances to be polished and media such as alumina beads or the like were charged together with pure water into a barrel container with a predetermined volume, and the barrel container is driven for a predetermined time so that the surface roughness Ra of the p-type semiconductor layer 1 is 1.0 μm or less to surface polish the substance to be polished. In addition, a driving time of the barrel container varies depending on a volume of the barrel container and charged amounts of the substance to be polished and the medium, and it is preferably about 5 to 20 minutes. That is, when the driving time of the barrel container is too long, there is a possibility that the medium adheres to the surface of the p-type semiconductor layer 1 to form projections and depressions newly, resulting in a reduction of a photocurrent.

By employing the method including a second polishing step of surface-polishing the p-type semiconductor layer 1 as a substance to be polished, as described above, wherein in the second polishing step, the p-type semiconductor layer 1 is surface polished so that its surface roughness is 1.0 μm or less, the p-type semiconductor layer 1 is properly joined to the n-type semiconductor layer 2, and the depletion layer is formed in both of the vicinity of an interface on an n-type semiconductor layer 2 side and the vicinity of an interface on a p-type semiconductor layer 1 side, and thereby an ultraviolet sensor extremely sharply responding to 350 to 370 nm and responding to ultraviolet light of 230 to 330 nm can be obtained. Further, since the p-type semiconductor layer 1 is surface polished, a probability of a junction region of the n-type semiconductor layer 2 and the p-type semiconductor layer 1 is increased, and an effective area is increased and reflected light can be used, and therefore absorption efficiency is increased and response intensity becomes high.

Further, when both of the formed product and the p-type semiconductor layer 1 are surface polished, both of the first polishing step and the second polishing step may be performed, and thereby, there is synergy between the effect of surface polishing before firing and the effect of surface polishing after firing, and a highly reliable ultraviolet sensor which has a larger photocurrent at a wide wavelength band of 230 to 370 nm can be obtained.

As described above, in accordance with the manufacturing method of the present invention, by surface polishing the formed product and/or the p-type semiconductor layer 1 to adjust the surface roughness Ra to 1.0 μm or less, an ultraviolet sensor, which can directly detect a large photocurrent responding to various wavelength bands even in the case of the same material system and has high sensitivity of light receiving at any desired absorption wavelength band, can be realized.

In addition, the present invention is not limited to the above-mentioned embodiment. In the above embodiment, a paste for forming an internal electrode containing a composite oxide is prepared, and the paste for forming an internal electrode is applied onto the surface of a (Ni, Zn)O green sheet and fired to form an internal electrode 4. However, a desired internal electrode can also be formed by preparing a rare earth paste including a principal component composed of a rare earth oxide R₂O₃ without allowing the paste for forming an internal electrode to include Ni, and diffusing Ni in the (Ni, Zn)O green sheet toward a rare earth film side during firing the rare earth paste.

Next, examples of the present invention will be described in detail.

### EXAMPLES

[Preparation of Sample]

(Sample Nos. 2 to 6)

[Preparation of ZnO Sintered Body]

ZnO serving as a principal component and Ga₂O₃ as a doping agent were weighed so that compounding ratios of these compounds were 99.9 mol % and 0.1 mol %, respectively. Then, after pure water was added to these weighed compounds, the resulting mixture was mixed and pulverized in a ball mill using PSZ beads as a pulverizing medium to obtain a slurry-like mixture of particles having an average particle diameter of 0.5 μm or less. Subsequently, after the slurry-like mixture was dehydrated and dried, the slurry was granulated to have a particle diameter of about 50 μm, and then resulting grains were calcinated for 2 hours at 1200° C. to obtain a calcined powder.

Next, after pure water was again added to the calcined powder thus obtained, the resulting mixture was mixed and pulverized in a ball mill using PSZ beads as a pulverizing medium to obtain a slurry-like pulverized material of particles having an average particle diameter of 0.5 μm. Then, the slurry-like pulverized material was dehydrated and dried, and then pure water and a dispersing agent were added thereto, and the resulting mixture was mixed, and a binder and a plasticizer were further added to prepare a slurry for forming. The slurry for forming was formed into a green sheet having a thickness of 20 μm by using a doctor blade method. Subsequently, the predetermined number of the green sheets was laminated to have a thickness of 20 mm, and was then press-boned for 5 minutes at a pressure of 250 MPa to obtain a press-boned product. After the press-boned product was degreased, it was fired at 1200° C. for 20 hours to obtain a ZnO sintered body.

[Preparation of (Ni, Zn)O Green Sheet]

A NiO powder and a ZnO powder were weighed so that the proportion of moles between these compounds was 7:3, and pure water was added to these weighed compounds, and the resulting mixture was mixed and pulverized by a ball mill using PSZ beads as a pulverizing medium to obtain a slurry-like mixture. Subsequently, after the slurry-like mixture was dehydrated and dried, the slurry was granulated to have a particle diameter of about 50 μm, and then resulting grains were calcinated for 2 hours at 1200° C. to obtain a calcined powder. Next, after pure water was again added to the calcined powder thus obtained, the resulting mixture was pulverized in a ball mill using PSZ beads as a pulverizing medium to obtain a slurry-like pulverized material of particles having an average particle diameter of 0.5 μm. Then, after the slurry-like pulverized material was dehydrated and dried, an organic solvent and a dispersing agent were added thereto, and the resulting mixture was mixed, and a binder and a plasticizer were further added to prepare a slurry for forming. The slurry for forming was formed into a (Ni, Zn)O green sheet having a thickness of 10 μm by using a doctor blade method.

[Paste for Internal Electrode]

A NiO powder and a La₂O₃ powder as a rare earth oxide were weighed so that the proportion of moles between these compounds was 2:1, and then pure water was added to these weighed compounds, and the resulting mixture was mixed and pulverized in a ball mill using PSZ beads as a pulverizing medium to obtain a slurry-like mixture. Subsequently, after the slurry-like mixture was dehydrated and dried, the slurry was granulated to have a particle diameter of about 50 μm, and then resulting grains were calcinated for 2 hours at 1200° C. to obtain a calcined powder. Next, after pure water was again added to the calcined powder thus obtained, the resulting mixture was pulverized in a ball mill using PSZ beads as a pulverizing medium to obtain a slurry-like pulverized material of particles having an average particle diameter of 0.5 μm. The slurry-like pulverized material was dehydrated and dried to obtain a LaNiO₃ powder. Thereafter, the obtained LaNiO₃ powder was mixed with an organic vehicle, and the resulting mixture was kneaded with a three roll mill to prepare a paste for forming an internal electrode.

In addition, the organic vehicle was prepared by mixing an ethyl cellulose resin and α-terpineol so that the percentage of the ethyl cellulose resin as a binder resin was 30 vol % and the percentage of α-terpineol as an organic solvent was 70 vol %.

[Preparation of Formed Product]

A paste for forming an internal electrode was applied onto the surface of one of the (Ni, Zn)O green sheets by a screen printing method, and dried for 1 hour at 60° C. to form a conductive film having a predetermined pattern.

Subsequently, 50 (Ni, Zn)O green sheets not provided with the conductive film were laminated, and a (Ni, Zn)O green sheet provided with the conductive film was laminated thereon, and further a (Ni, Zn)O green sheet not provided with the conductive film was laminated thereon. These sheets were press-bonded at a pressure of 200 MPa to form a laminate, and the resulting laminate was cut into a size of 2.5 mm×1.5 mm to prepare a formed product.

[Surface Polishing of Formed Product (Polishing Prior to Firing; First Polishing Step)]

100 formed products thus prepared were charged into a barrel container having a volumetric capacity of 5.0×10⁻⁴ m³ together with 0.5 kg of alumina beads of 1 mm in diameter, and the barrel container was rotated at a rotational speed of 2 rotation/second to perform barrel polishing for a polishing time shown in Table 1.

Then, the surface roughness Ra of each sample was measured with a laser microscope (VK-8700 manufactured by KEYENCE CORPORATION) after barrel polishing.

[Preparation of P-Type Semiconductor Layer]

The formed product subjected to barrel polishing was gradually and adequately degreased at 300° C., and then fired at 1200° C. for 1 hour in the air to obtain a p-type semiconductor layer.

Then, surface roughness Ra of the p-type semiconductor layer of each sample was measured with the above-mentioned laser microscope.

[Preparation of Terminal Electrode]

An Ag paste was applied to both ends of the p-type semiconductor layer and fired at 800° C. for 10 minutes to prepare a first and a second external electrodes. Then, the surfaces of the first and the second external electrodes were plated by electroplating to form a Ni coating and a Sn coating in succession, and thereby, a first terminal electrode and a second terminal electrode were prepared.

[Formation of N-Type Semiconductor Layer]

Sputtering was performed through a metal mask using a ZnO sintered body as a target so that an n-type semiconductor layer covers a part of one main surface of a p-type semiconductor layer and overlaps a part of a second terminal electrode to prepare an n-type semiconductor layer with a predetermined pattern having a thickness of about 0.5 μm, and thereby, samples of sample Nos. 2 to 6 were obtained.

(Sample Nos. 7 to 11)

Procedures from [Preparation of ZnO Sintered Body] to [Preparation of Formed Product] were performed by the same method/procedure as in the sample Nos. 2 to 6.

Then, surface roughness Ra of the formed product of each sample was measured with the laser microscope.

Then, the formed product not subjected to barrel polishing was gradually and adequately degreased at a temperature of 300° C., and then fired at 1200° C. for 1 hour in the air to obtain a p-type semiconductor layer.

Thereafter, the p-type semiconductor layer was subjected to polishing (polishing after firing; second polishing step). That is, 100 p-type semiconductor layers thus prepared were charged into a barrel container having a volumetric capacity of 5.0×10⁻⁴ m³ together with 0.5 kg of alumina beads of 1 mm in diameter and 1.0×10⁻⁴ m³ of pure water, and the barrel container was rotated at a rotational speed of 3.3 rotation/second to perform barrel polishing for a polishing time shown in Table 1.

Then, the surface roughness Ra of the p-type semiconductor layer of each sample was measured with the laser microscope.

Thereafter, procedures in [Preparation of Terminal Electrode] and [Formation of N-Type Semiconductor Layer] were performed by the same method/procedure as in the sample Nos. 2 to 6, and thereby, samples of sample Nos. 7 to 11 were prepared.

(Sample No. 12)

Procedures from [Preparation of ZnO Sintered Body] to [Polishing (Polishing prior to Firing; First Polishing Step) of Formed Product] were performed by the same method/procedure as in the sample Nos. 2 to 6.

Thereafter, as with the sample Nos. 7 to 11, the formed product subjected to barrel polishing was fired to prepare a p-type semiconductor layer, and then barrel polishing (polishing after firing; second polishing step) was performed.

Subsequently, procedures in [Preparation of Terminal Electrode] and [Formation of N-Type Semiconductor Layer] were performed by the same method/procedure as in the sample Nos. 2 to 6, and thereby, a sample of a sample No. 12 was prepared.

In addition, the surface roughness Ra of this sample No. 12 before and after firing was also measured with the laser microscope.

(Sample No. 1)

A sample of a sample No. 1 was prepared in the same manner as in the above-mentioned sample except for neither performing barrel polishing before firing nor after firing.

In addition, the surface roughness Ra of this sample No. 1 before and after firing was also measured with the laser microscope.

[Evaluation of Sample]

In each sample of sample Nos. 1 to 12, as shown in FIG. 3, an internal electrode 32 is embedded in a p-type semiconductor layer 31, a first terminal electrode 33a and a second terminal electrode 33b are formed at both ends of the p-type semiconductor layer 31, and an n-type semiconductor layer 34 is joined to the surface of the p-type semiconductor layer 31. Then, an ammeter 35 was interposed between the first terminal electrode 33a and the second terminal electrode 33b, and an outer surface on a side of the n-type semiconductor layer 34 of each sample was irradiated with ultraviolet light having a wavelength of 300 nm and ultraviolet light having a wavelength of 370 nm from an ultraviolet light source equipped with a spectroscope as shown by an arrow B in a darkroom, and a photocurrent flowing between the first terminal electrode 33a and the second terminal electrode 33b was measured.

Further, a short circuit test and an open test of 20 samples of each of sample Nos. 1 to 12 were carried out and reliability was evaluated. Herein, in the short circuit test, resistance between the first terminal electrode 33a and the second terminal electrode 33b was measured with a tester, and a sample having a resistance of 1 MΩ or less was considered as a short circuit defect and the sample causing the short circuit defect was counted and evaluated. Further, in the open test, resistance between the first terminal electrode 33a and the second terminal electrode 33b was measured with a high insulation tester, and a sample having a resistance of 1 GΩ or more was considered as an open defect and the sample causing the open defect was counted and evaluated.

In addition, the irradiation intensity of light was set at 0.5 mW/cm² in the case of a wavelength of 300 nm and 1 mW/cm² in the case of a wavelength of 370 nm, and the measurement temperature was controlled to be 25° C.±1° C.

Table 1 shows a polishing time, a surface roughness Ra, and a photocurrent of the sample Nos. 1 to 12, and the number of samples of a short circuit defect and the number of samples of an open defect in 20 samples for each sample No.

TABLE 1

| | | | Surface | | | | | |
|---|---|---|---|---|---|---|---|---|
| | Polishing Time | | Roughness | | | | | |
| | (min) | | Ra (μm) | | Photocurrent (nA) | | Short | |
| Sample | Before | After | Before | After | Wavelength: | Wavelength: | Circuit | Open |
| No. | Firing | Firing | Firing | Firing | 300 nm | 370 nm | Defect | Defect |
| 1* | — | — | 1.5 | 2.0 | 10 | 3 | 5/20 | 7/20 |
| 2 | 60 | — | 1.0 | 1.5 | 25 | 4 | 1/20 | 2/20 |
| 3 | 120 | — | 0.7 | 1.3 | 50 | 8 | 0/20 | 0/20 |
| 4 | 240 | — | 0.5 | 1.3 | 43 | 7 | 0/20 | 0/20 |
| 5 | 480 | — | 0.5 | 1.4 | 40 | 6 | 0/20 | 1/20 |
| 6 | 960 | — | 0.4 | 1.3 | 38 | 5 | 0/20 | 1/20 |
| 7 | — | 5 | 1.5 | 1.0 | 25 | 40 | 1/20 | 0/20 |
| 8 | — | 10 | 1.5 | 0.8 | 48 | 100 | 1/20 | 0/20 |
| 9 | — | 20 | 1.5 | 0.5 | 40 | 85 | 0/20 | 0/20 |
| 10 | — | 40 | 1.5 | 0.4 | 32 | 60 | 1/20 | 0/20 |
| 11 | — | 60 | 1.5 | 0.3 | 15 | 34 | 1/20 | 0/20 |
| 12 | 120 | 10 | 0.7 | 0.8 | 74 | 150 | 0/20 | 0/20 |

*indicates out of the scope of the present invention

Since the sample No. 1 was not surface polished at all before and after firing, the surface roughness Ra prior to firing was 1.5 μm, and the surface roughness Ra after firing was 2.0 μm. That is, since the surface roughness Ra is out of the present invention, the resulting photocurrent was as small as 10 nA at a wavelength of 300 nm and 3 nA at a wavelength of 370 nm. The reason for this is probably that since the surface roughness Ra is large, the p-type semiconductor layer 31 is not properly joined to the n-type semiconductor layer 34, ultraviolet light caused diffuse reflection at a junction interface or the like, and therefore light absorption efficiency was deteriorated.

Further, in the sample No. 1, the short circuit defect occurs in 5 samples in 20 samples and the open defect occurs in 7 samples in 20 samples, and the sample No. 1 was found to be inferior in reliability. The reason for this is a probability that unnecessary contact resistance or a junction defect occurs between the internal electrode 32 and the first terminal electrodes 33a is increased, or defects such as pinhole, which are formed at the formed product, remain at the surface of the p-type semiconductor layer 31.

On the other hand, since the sample Nos. 2 to 6 were polished before firing so that the surface roughness Ra was 1.0 μm or less, the surface roughness Ra after firing can be suppressed to 1.5 μm or less, and photocurrents of 25 nA to 50 nA could be attained for ultraviolet light with a wavelength of 300 nm. The reason for this is probably that light absorption efficiency is improved, and a depletion layer is formed in the vicinity of a surface layer on a p-type semiconductor layer 31 side by polishing before firing, and a large photocurrent could be obtained at 300 nm which is an absorption wavelength band of (Ni, Zn)O. Further, it was found that the short circuit defect and the open defect can be decreased to 0 to 2 samples in 20 samples by adjusting the surface roughness Ra prior to firing to 1.0 μm or less. The reason for this is probably that since a joining property between the internal electrode 32 and the first terminal electrode 33a is improved, unnecessary contact resistance and a junction defect are inhibited, and defects such as a pinhole which is formed at the surface of the formed product can be removed to reduce a short circuit defect.

The sample Nos. 7 to 11 could obtain a large photocurrent at a wavelength of 370 nm. The reason for this is probably that in the sample Nos. 7 to 11, since polishing is performed after firing so that the surface roughness Ra is 1.0 μm or less, the surface of the p-type semiconductor layer 31, in which the amount of carrier is small, is scraped off, and consequently light absorption efficiency is improved, junction becomes better, and a large photocurrent was obtained not only at a wavelength band of 230 to 330 nm originated from (Ni, Zn)O, but also at a wavelength of 370 nm originated from ZnO. Further, the short circuit defect and the open defect were decreased to 0 to 1 sample in 20 samples.

The sample No. 12 could attain large photocurrents of 74 nA for ultraviolet light with a wavelength of 300 nm and 150 nA for ultraviolet light with a wavelength of 370 nm since barrel polishing is performed before firing and after firing.

Next, with reference to the sample Nos. 1 and 3, a wavelength responsive property at the time when the irradiance was set at 0.5 mW/cm² and the wavelength of the ultraviolet light source was varied in increments of 10 nm from 200 nm to 600 nm was investigated.

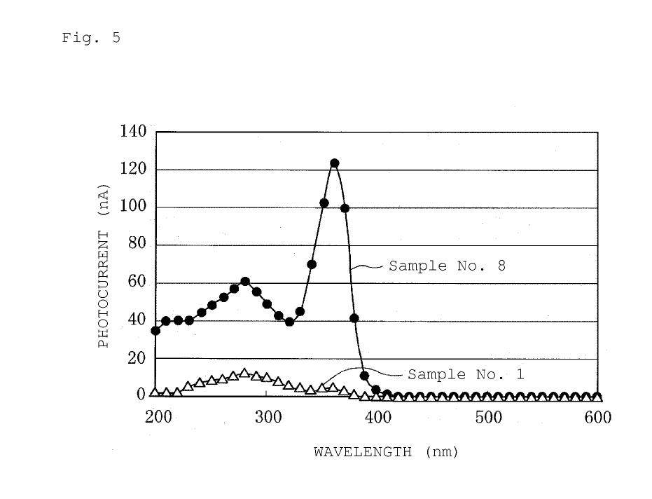

FIG. 4 shows the measurement results, and a horizontal axis represents a wavelength (nm) and a vertical axis represents an output current (nA). In FIG. 4, a symbol Δ indicates the wavelength responsive property of the sample No. 1 and a symbol • indicates the wavelength responsive property of the sample No. 3.

As is apparent from FIG. 4, the sample No. 3 strongly responds to ultraviolet light with a wavelength of 230 to 330 nm in which a wavelength of 280 nm is a peak, and the sample No. 3 was found to have a good wavelength responsive property in wavelength bands of UV-B and UV-C.

On the other hand, the sample No. 1 also responds to ultraviolet light with a wavelength of 230 to 330 nm in which a wavelength of 280 nm is a peak as with the sample No. 3, but it was found that the sample No. 1 can attain only a small photocurrent.

Next, with reference to the sample Nos. 1 and 8, a wavelength responsive property at the time when the irradiance was set at 1 mW/cm² and the wavelength of the ultraviolet light source was varied in increments of 10 nm from 200 nm to 600 nm was investigated.

FIG. 5 shows the measurement results, and a horizontal axis represents a wavelength (nm) and a vertical axis represents an output current (nA). In FIG. 5, a symbol Δ indicates the wavelength responsive property of the sample No. 1 and a symbol • indicates the wavelength responsive property of the sample No. 8.

As is apparent from FIG. 5, the sample No. 1 responds to ultraviolet light with a wavelength of 230 to 330 nm, but it can attain only a small photocurrent, and on the other hand, the sample No. 8 responds to ultraviolet light having a wavelength band of 230 to 330 nm in which a wavelength of 280 nm is a peak and ultraviolet light having a wavelength band of 350 to 370 nm in which a wavelength of 360 nm is a peak, and the sample No. 8 was found to have a good wavelength responsive property in wide wavelength bands of UV-A, UV-B and UV-C.

Light absorption efficiency is high, reliability is excellent, and high sensitivity of light-receiving can be attained at various wavelength bands according to uses.

### DESCRIPTION OF REFERENCE SYMBOLS

1 p-type semiconductor layer
2 n-type semiconductor layer
3a first terminal electrode
3b second terminal electrode
4 internal electrode
5a to 5n (Ni, Zn)O green sheet
6 conductive film

1. An ultraviolet sensor comprising:
a p-type semiconductor layer composed of a solid solution of NiO and ZnO;
an n-type semiconductor layer composed of ZnO and joined to a surface of the p-type semiconductor layer such that a part of the surface is exposed;
an internal electrode embedded in the p-type semiconductor layer; and
terminal electrodes at opposed ends of the p-type semiconductor layer, wherein
the p-type semiconductor layer has a surface roughness of 1.5 μm or less.

2. The ultraviolet sensor according to claim 1, wherein the surface roughness of the p-type semiconductor layer is 1.0 μm or less.

3. The ultraviolet sensor according to claim 2, wherein the surface roughness of the p-type semiconductor layer is not less than 0.3 μm.

4. The ultraviolet sensor according to claim 1, wherein the surface roughness of the p-type semiconductor layer is not less than 0.3 μm.

5. A method for manufacturing an ultraviolet sensor, the method comprising:
preparing a plurality of green sheets each composed of a solid solution of NiO and ZnO;
applying a conductive paste onto the surface of a green sheet of the plurality of green sheets to form a conductive film having a predetermined pattern;
laminating the plurality of the green sheets such that the green sheet having the conductive film formed thereon is sandwiched by other green sheets of the plurality of green sheets to form a formed product;
surface-polishing the formed product to have a surface roughness of 1.0 μm or less before firing the formed product; and
firing the formed product to prepare a p-type semiconductor layer.

6. The method for manufacturing an ultraviolet sensor according to claim 5, wherein the formed product is surface-polished to have the surface roughness from 1.0 μm to not less than 0.3 μm.

7. The method for manufacturing an ultraviolet sensor according to claim 5, wherein as the surface polishing, barrel polishing is performed by charging the substance to be polished into a container together with media, and rotating, vibrating, inclining or swinging the container.

8. The method for manufacturing an ultraviolet sensor according to claim 5, further comprising forming an n-type semiconductor layer composed of ZnO on the surface of the p-type semiconductor layer such that a part of the surface of the p-type semiconductor layer is exposed, wherein the n-type semiconductor layer is formed by preparing a ZnO sintered body composed of ZnO, and sputtering by using the ZnO sintered body as a target to form the n-type semiconductor layer.

9. The method for manufacturing an ultraviolet sensor according to claim 5, further comprising forming terminal electrodes at opposed ends of the p-type semiconductor layer.

10. The method for manufacturing an ultraviolet sensor according to claim 5, the method further comprising surface-polishing the p-type semiconductor layer to have a surface roughness of 1.0 μm or less.

11. The method for manufacturing an ultraviolet sensor according to claim 10, wherein the formed product is surface-polished to have the surface roughness from 1.0 μm to not less than 0.3 μm.

12. The method for manufacturing an ultraviolet sensor according to claim 10, wherein the p-type semiconductor layer is surface-polished to have the surface roughness from 1.0 μm to not less than 0.3 μm.

13. The method for manufacturing an ultraviolet sensor according to claim 10, wherein as the surface polishing, barrel polishing is performed by charging the substance to be polished into a container together with media, and rotating, vibrating, inclining or swinging the container.

14. The method for manufacturing an ultraviolet sensor according to claim 10, further comprising forming an n-type semiconductor layer composed of ZnO on the surface of the p-type semiconductor layer such that a part of the surface of the p-type semiconductor layer is exposed, wherein the n-type semiconductor layer is formed by preparing a ZnO sintered body composed of ZnO, and sputtering by using the ZnO sintered body as a target to form the n-type semiconductor layer.

15. The method for manufacturing an ultraviolet sensor according to claim 10, further comprising forming terminal electrodes at opposed ends of the p-type semiconductor layer.

16. A method for manufacturing an ultraviolet sensor, the method comprising:
preparing a plurality of green sheets composed of a solid solution of NiO and ZnO;
applying a conductive paste onto the surface of a green sheet of the plurality of green sheets to form a conductive film having a predetermined pattern;
laminating the plurality of the green sheets such that the green sheet having the conductive film formed thereon is sandwiched by other green sheets of the plurality of green sheets to form a formed product;
surface-polishing the formed product to have a surface roughness of 1.0 μm or less before firing the formed product;
firing the formed product to form a p-type semiconductor layer; and
surface-polishing the p-type semiconductor layer to have a surface roughness of 1.0 μm or less.

17. The method for manufacturing an ultraviolet sensor according to claim 16, wherein as the surface polishing, barrel polishing is performed by charging the substance to be polished into a container together with media, and rotating, vibrating, inclining or swinging the container.

18. The method for manufacturing an ultraviolet sensor according to claim 16, further comprising forming an n-type semiconductor layer composed of ZnO on the surface of the p-type semiconductor layer such that a part of the surface of the p-type semiconductor layer is exposed, wherein the n-type semiconductor layer is formed by preparing a ZnO sintered body composed of ZnO, and sputtering by using the ZnO sintered body as a target to form the n-type semiconductor layer.

19. The method for manufacturing an ultraviolet sensor according to claim 16, further comprising forming terminal electrodes at opposed ends of the p-type semiconductor layer.

20. The method for manufacturing an ultraviolet sensor according to claim 16, wherein both the formed product and the p-type semiconductor layer are surface-polished to have the surface roughness from 1.0 μm to not less than 0.3 μm.
